(19) United States
(12) Patent Application Publication
(10) Pub. No.: US 2026/0247677 A1
(43) Pub. Date: Aug. 20, 2026

(54) SEMICONDUCTOR DEVICE AND METHOD FOR FABRICATING THE SAME

(71) Applicant: SK hynix Inc., Gyeonggi-do (KR)

(72) Inventors: Jun Sik KIM, Gyeonggi-do (KR); Sung Hwan HWANG, Gyeonggi-do (KR)

(21) Appl. No.: 19/647,910

(22) Filed: Apr. 15, 2026

Related U.S. Application Data
(62) Division of application No. 18/301,991, filed on Apr. 18, 2023, now abandoned.

(30) Foreign Application Priority Data
Nov. 10, 2022 (KR) 10-2022-0149588

(51) Int. Cl. H10D 64/01; H10D 64/27; H10D 64/68; H10B 12/00; H10D 64/66

(52) U.S. Cl. CPC H10D 64/01; H10D 64/01332; H10D 64/513; H10D 64/685; H10D 64/691; H10B 12/01; H10D 64/667

(57) ABSTRACT

A semiconductor device includes a gate trench formed in a substrate, a gate dielectric layer formed along profile of sidewalls and a bottom surface of the gate trench, first and second gate electrodes that are stacked over the gate dielectric layer to gap-fill a portion of the gate trench, a dipole inducing portion positioned between the second gate electrode and the gate dielectric layer and including a dipole bond and a non-dipole bond, and a capping layer suitable for gap-filling a remaining portion of the gate trench over the dipole inducing portion and the second gate electrode.

### CROSS-REFERENCE TO RELATED APPLICATIONS

The present application is a division of U.S. Patent Application No. 18/301,991 filed on April 18, 2023, which claims priority of Korean Patent Application No. 10-2022-0149588, filed on November 10, 2022, which is incorporated herein by reference in its entirety.

### BACKGROUND

### 1. Field

The present invention relates generally to a semiconductor device and, more particularly, to a semiconductor device including a buried gate, and a method for fabricating the same.

### 2. Description of the Related Art

As semiconductor memory devices are being highly integrated, line widths of buried word lines are decreasing. In particular, when polysilicon is used for a double gate electrode to improve gate-induced drain leakage (GIDL) characteristics, there is a problem in that resistance increases due to the decrease in line widths of the word lines. Therefore, it would be highly desirable to develop new structures which solve the problem of the increased resistance of word lines while improving the GIDL characteristics.

### SUMMARY

Various embodiments of the present invention are directed to a semiconductor device with improved electrical characteristics, and a method for fabricating the semiconductor device.

In accordance with an embodiment of the present invention, a semiconductor device includes: gate trench formed in a substrate; a gate dielectric layer formed along profile of sidewalls and a bottom surface of the gate trench; first and second gate electrodes that are stacked over the gate dielectric layer to gap-fill a portion of the gate trench; a dipole inducing portion positioned between the second gate electrode and the gate dielectric layer and including a dipole bond and a non-dipole bond; and a capping layer suitable for gap-filling a remaining portion of the gate trench over the dipole inducing portion and the second gate electrode.

In accordance with another embodiment of the present invention, a method for fabricating a semiconductor device includes: forming gate trench in a substrate; forming a gate dielectric layer along profile of sidewalls and a bottom surface of the gate trench; forming a first gate electrode over the gate dielectric layer to gap-fill the bottom surface of the gate trench; forming a dipole inducing layer including a dipole bond over an exposed surface of the gate dielectric layer; forming a second gate electrode over the first gate electrode and the dipole inducing layer to gap-fill a portion of the gate trench; etching the dipole inducing layer to the same level as an top surface of the second gate electrode to form a dipole inducing portion; performing an impurity ion implantation process for a non-dipole bond onto the dipole inducing portion; and forming a capping layer to gap-fill a remaining portion of the gate trench over the dipole inducing portion and the second gate electrode.

### BRIEF DESCRIPTION OF THE DRAWINGS

FIG. 1 is a plan view illustrating a semiconductor device in accordance with embodiments of the present invention.

FIG. 2A is a cross-sectional view of the semiconductor device taken along a line A-A’ shown in FIG. 1.

FIG. 2B is a cross-sectional view of the semiconductor device taken along a line B-B’ shown in FIG. 1.

FIGS. 3A to 3L are cross-sectional views illustrating a method for fabricating a semiconductor device in accordance with an embodiment of the present invention.

FIG. 4 is a cross-sectional view illustrating a semiconductor device in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

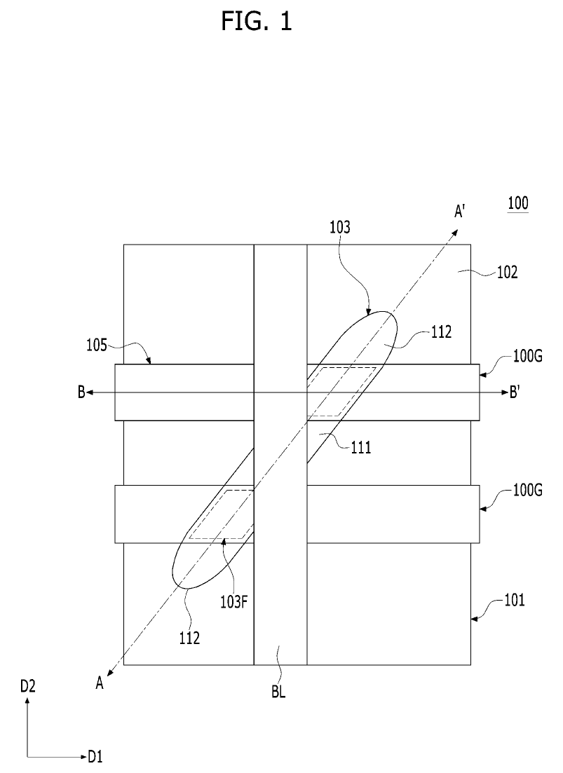

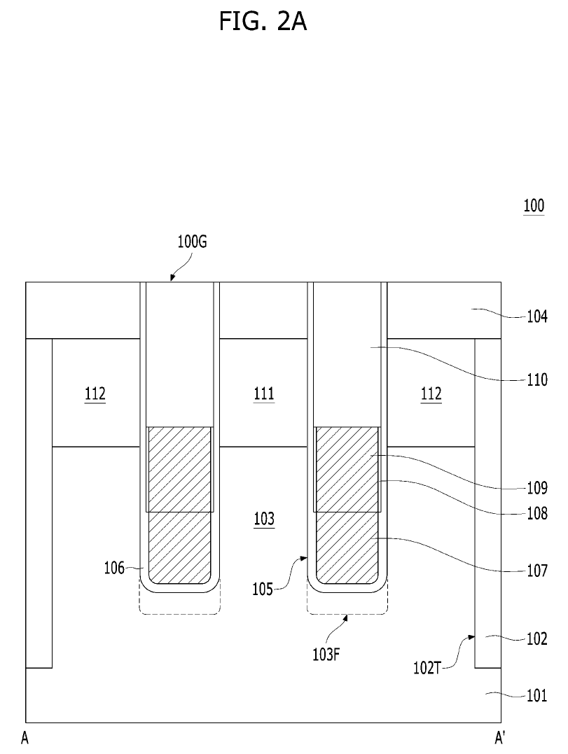

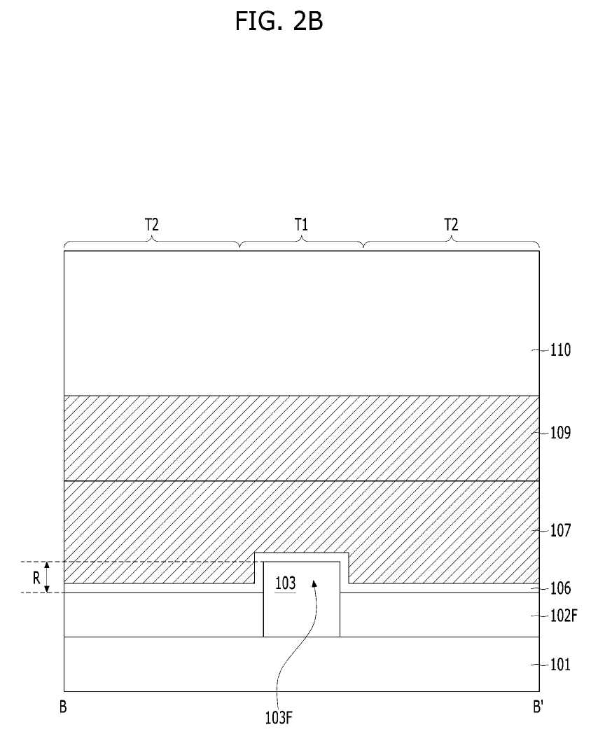

FIG. 1 is a plan view illustrating a semiconductor device 100 in accordance with embodiments of the present invention. FIG. 2A is a cross-sectional view of the semiconductor device 100 taken along a line A-A’ shown in FIG. 1. FIG. 2B is a cross-sectional view of the semiconductor device 100 taken along a line B-B’ shown in FIG. 1.

Referring to FIGS. 1, 2A and 2B, the semiconductor device 100 may include a substrate 101 and a buried gate structure 100G which is embedded in the substrate 101. The semiconductor device 100 may be part of memory cells, such as, for example, memory cells of a Dynamic Random Access Memory (DRAM).

The substrate 101 may be made of any material that is suitable for semiconductor processing. For example, the substrate 101 may include a semiconductor substrate, such as, a substrate formed of a silicon-containing material. The substrate 101 may also include other semiconductor materials, such as germanium (Ge) In an embodiment, the substrate 101 may be a compound semiconductor substrate. In an embodiment, the substrate 101 may be a III/V-group compound semiconductor substrate, such as, for example, a gallium arsenide (GaAs) semiconductor substrate. In an embodiment, the substrate 101 may include a Silicon-On-Insulator (SOI) substrate. Examples of suitable materials for the substrate 101 may include silicon, monocrystalline silicon (also referred to as single crystal silicon), polysilicon, amorphous silicon, silicon germanium, monocrystalline silicon germanium, polycrystalline silicon germanium, carbon-doped silicon, a combination thereof, or a multi-layer thereof.

An isolation layer 102 and an active region 103 may be formed over the substrate 101. The active region 103 may be defined by the isolation layer 102. The isolation layer 102 may be a shallow trench isolation region (STI) which is formed by trench etching. The isolation layer 102 may be formed by filling a shallow trench, for example, an isolation trench 102T, with a dielectric material. Suitable materials for the isolation layer 102 may include, for example, silicon oxide, silicon nitride, or a combination thereof.

A gate trench 105 may be formed in the substrate 101. The gate trench 105 may be formed by using a hard mask layer 104 as an etch barrier and etching the substrate 101. From the perspective of a plan view shown in FIG. 1, the gate trench 105 may have a line shape extending in a first direction D1. The gate trench 105 may have a line shape crossing the active region 103 and the isolation layer 102. The gate trench 105 may have a shallower depth than the isolation trench 102T. The bottom portion of the gate trench 105 may be flat with curbed edges connected to the sidewalls of the gate trench 105, for example, as shown in the embodiment of FIG. 2A. However, according to another embodiment of the present invention (not shown), the bottom portion of the gate trench 105 may itself have a curvature. The gate trench 105 provides a space inside which the buried gate structure 100G is formed.

A first doped region 111 and a second doped region 112 may be formed in the active region 103. The first doped region 111 and the second doped region 112 may be regions doped with a conductive dopant. For example, the conductive dopant may include phosphorus (P), arsenic (As), antimony (Sb), or boron (B). The first doped region 111 and the second doped region 112 may be doped with dopants of the same conductivity type. The first doped region 111 and the second doped region 112 may be positioned in the active region 103 on both sides of the gate trench 105. The bottom surfaces of the first doped region 111 and the second doped region 112 may be positioned at a predetermined depth from the top surface of the active region 103. The bottom surfaces of the first doped region 111 and the second doped region 112 may be higher than the bottom surface of the gate trench 105. The first doped region 111 may be referred to as a ‘first source/drain region’, and the second doped region 112 may be referred to as a ‘second source/drain region’. A channel (not shown) may be defined between the first doped region 111 and the second doped region 112 by the buried gate structure 100G. The channel may be defined along the profile of the gate trench 105.

The gate trench 105 may include a first trench T1 and a second trench T2. The first trench T1 may be formed in the active region 103. The second trench T2 may be formed in the isolation layer 102. The gate trench 105 may continuously extend as it goes from the first trench T1 to the second trench T2. In the gate trench 105, the bottom surface of the first trench T1 may be positioned at a higher level than the bottom surface of the second trench T2. The height difference between the first trench T1 and the second trench T2 may be formed as the isolation layer 102 is recessed. Accordingly, the second trench T2 may include a recess region R having a lower bottom surface than the bottom surface of the first trench T1. A fin 103F may be formed in the active region 103 due to the step height difference between the first trench T1 and the second trench T2. Thus, the active region 103 may include the fin 103F.

In this way, the fin 103F may be formed below the first trench T1, and the sidewalls of the fin 103F may be exposed by the recessed isolation layer 102F. The fin 103F may be a portion in which a portion of the channel (not shown) is formed. The fin 103F may be referred to as a saddle fin. The fin 103F may increase the channel width and improve the electrical characteristics.

According to another embodiment of the present invention, the fin 103F may be omitted.

A buried gate structure 100G may be embedded in the gate trench 105. The buried gate structure 100G may extend into the isolation layer 102 while being positioned in the active region 103 between the first doped region 111 and the second doped region 112. In the buried gate structure 100G, the bottom surface of the portion positioned in the active region 103 and the bottom surface of the portion positioned in the isolation layer 102 may be positioned at different levels. When the fin 103F is omitted, the bottom surface of the portion positioned in the active region 103 and the bottom surface of the portion positioned in the isolation layer 102 may be positioned at the same level in the buried gate structure 100G.

The buried gate structure 100G may include a gate dielectric layer 106, a first gate electrode 107, a dipole inducing portion 108, a second gate electrode 109, and a capping layer 110.

The gate dielectric layer 106 may be conformally formed on the bottom surface and sidewalls of the gate trench 105. The gate dielectric layer 106 may include, for example, silicon oxide, silicon nitride, silicon oxynitride, a high-k material, or a combination thereof. The high-k material may include a material having a higher dielectric constant than that of silicon oxide. For example, the high-k material may include a material having a greater dielectric constant than approximately 3.9. According to another example, the high-k material may include a material having a greater dielectric constant than approximately 10. According to another example, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may be selectively used. The gate dielectric layer 106 may include a metal oxide.

The top surface of the first gate electrode 107 may be positioned at a lower level than bottom surfaces of the first and second doped regions 111 and 112. Accordingly, the first gate electrode 107 may not horizontally overlap with the first and second doped regions 111 and 112. The first gate electrode 107 may include, for example, a metal nitride. For example, the first gate electrode 107 may include titanium nitride (TiN). In particular, according to an embodiment of the present invention, the first gate electrode 107 may include fluorine-free titanium nitride (TiN).

The top surface of the second gate electrode 109 may be positioned at a lower level than the top surfaces of the first and second doped regions 111 and 112. The second gate electrode 109 may overlap with all or part of the first and second doped regions 111 and 112 horizontally. The second gate electrode 109 may include the same metal nitride as that of the first gate electrode 107. For example, the second gate electrode 109 may include titanium nitride (TiN). In particular, according to an embodiment of the present invention, the first gate electrode 107 may include fluorine-free titanium nitride (TiN).

The dipole inducing portion 108 may be positioned between the sidewalls of the second gate electrode 109 and the gate dielectric layer 106. The dipole inducing portion 108 may induce a dipole into the gate dielectric layer 106. Therefore, gate induced drain leakage (GIDL) may be improved. The top surface of the dipole inducing portion 108 may be positioned at the same level as the top surface of the second gate electrode 109. In other words, the top surface of the dipole inducing portion 108 may be positioned at a lower level than the top surfaces of the first and second doped regions 111 and 112.

The dipole inducing portion 108 may include a product of reaction between dipole-inducing chemical species and the gate dielectric layer 106. The dipole inducing portion 108 may include silicon oxide containing dipole-inducing chemical species. For example, the dipole-inducing chemical species may include lanthanum (La). In other words, the dipole inducing portion 108 may include silicon oxide containing lanthanum (La). For example, the dipole inducing portion 108 may include a product of reaction between lanthanum oxide (La₂O₃) and the gate dielectric layer 106. In other words, the dipole inducing portion 108 may include lanthanum silicate. As described above, the coupling of a dipole-inducing chemical species for formation of a dipole may be referred to as a ‘dipole bond’. In other words, dipole bond may be lanthanum silicate.

In particular, the dipole inducing portion 108 of this embodiment of the present invention may further include a non-dipole bond in addition to the dipole bond. The non-dipole bond may refer to a bond between the unreacted dipole-inducing chemical species remaining after the dipole bond is formed in the dipole inducing portion 108 and an impurity. In other words, the dipole inducing portion 108 may include a dipole bond and a non-dipole bond, and there is no unreacted dipole-inducing chemical species remaining in the dipole inducing portion 108. Therefore, problems such as a short between contacts due to external diffusion of the unreacted dipole-inducing chemical species may be prevented.

A non-dipole bond may be formed through an impurity that does not affect the dipole characteristics while having a high bonding strength with a dipole-inducing chemical species at the same time. The impurity used for the non-dipole bond may include, for example, fluorine, but the concept and spirit of the present invention are not limited thereto. For example, when the dipole-inducing chemical species is lanthanum (La) and the impurity is fluorine (F), the non-dipole bond may include a lanthanum-fluorine (La-F) bond.

The capping layer 110 may serve to protect the second gate electrode 109. The capping layer 110 may include a dielectric material. The capping layer 110 may include silicon nitride, silicon oxynitride, or a combination thereof. According to another embodiment of the present invention, the capping layer 110 may include a combination of silicon nitride and silicon oxide. According to yet another embodiment of the present invention, the capping layer 110 may include a silicon nitride liner and a Spin-On-Dielectric (SOD) material.

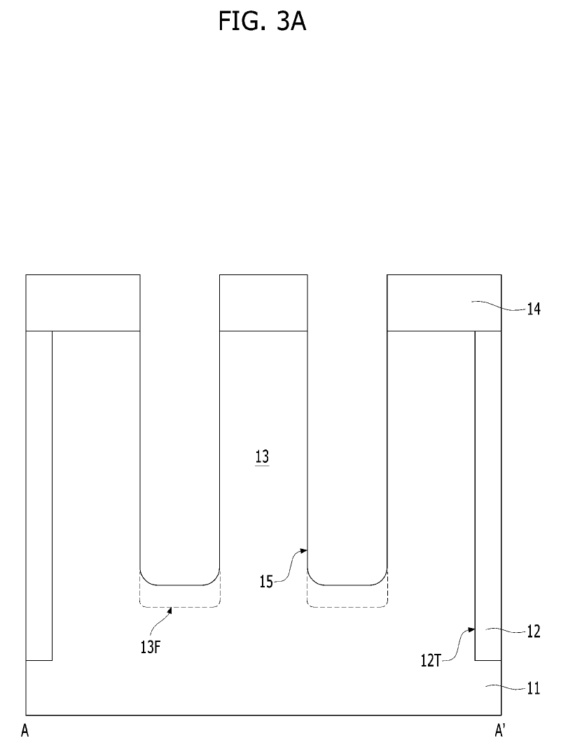

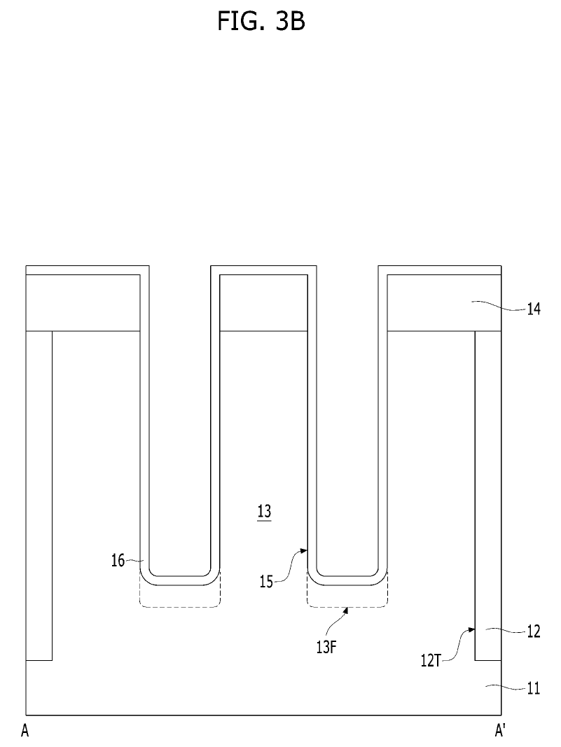

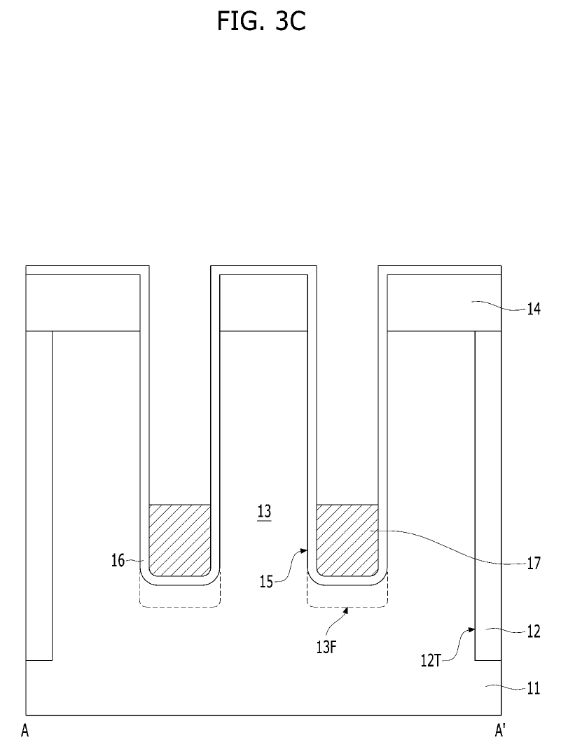

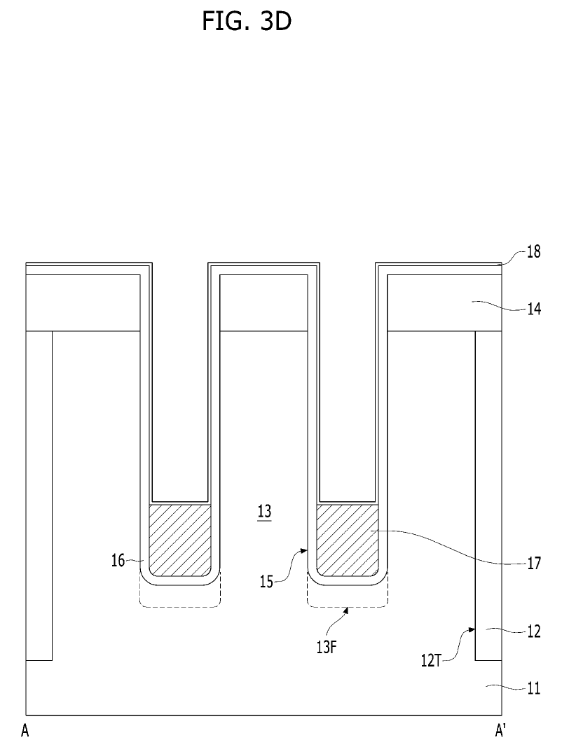

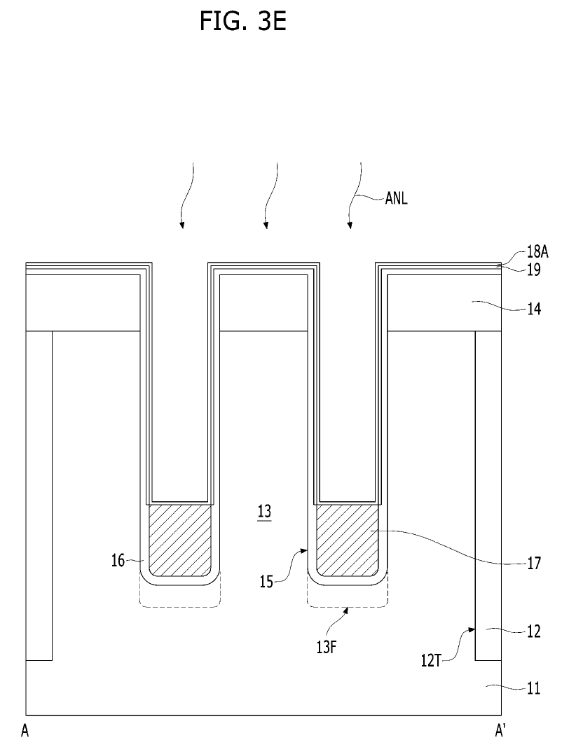

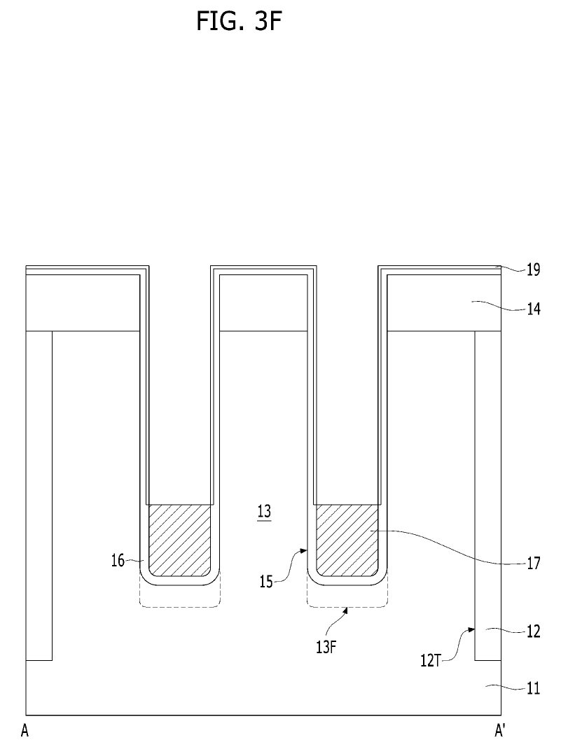

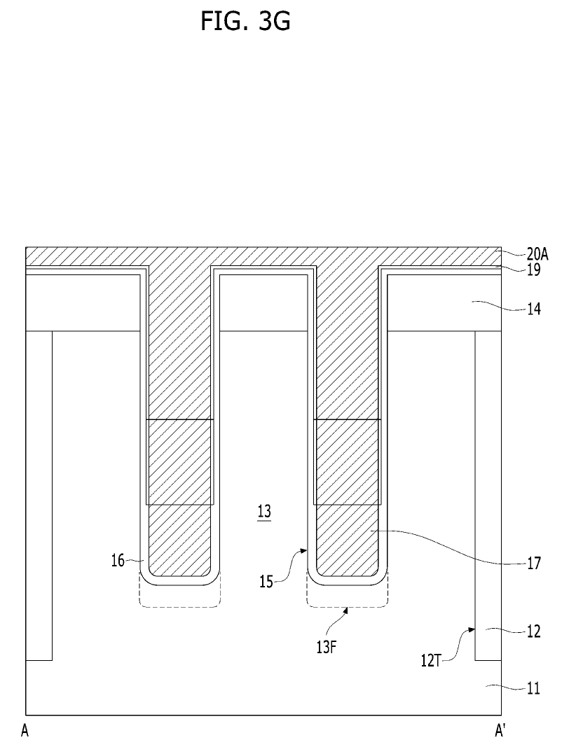

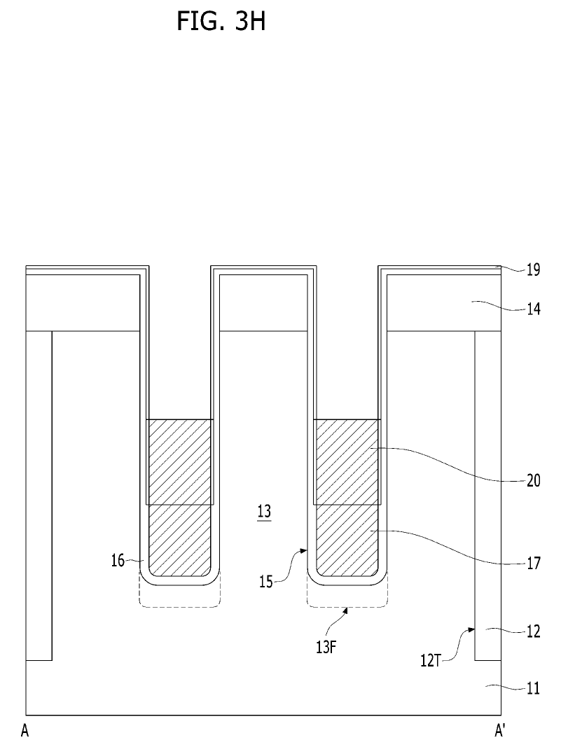

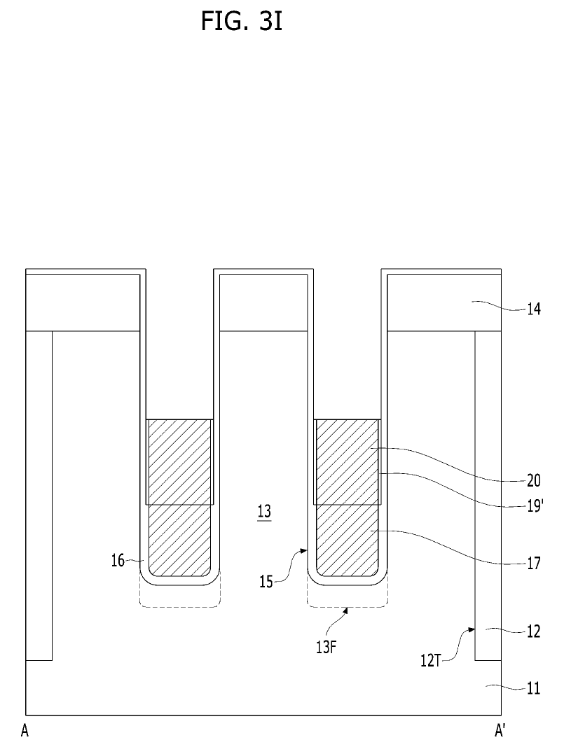

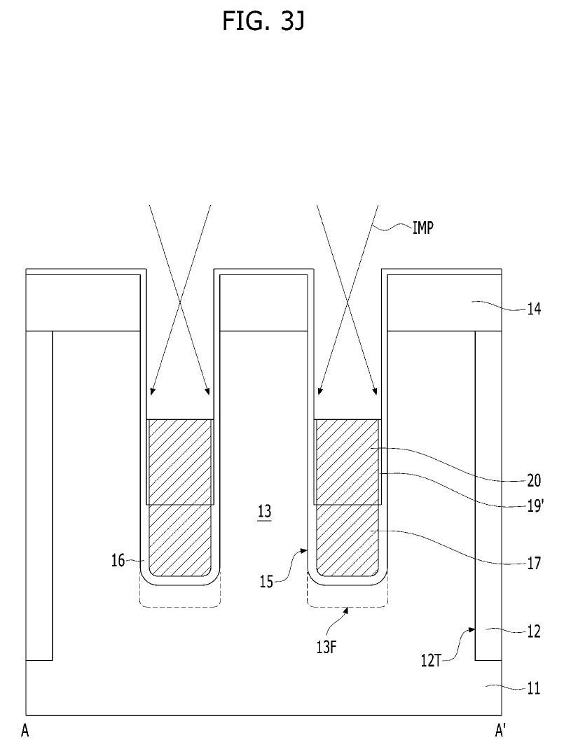

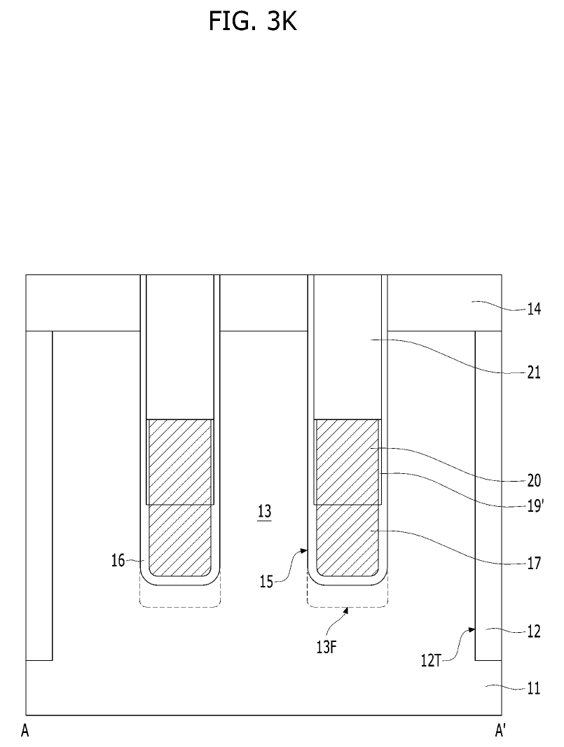

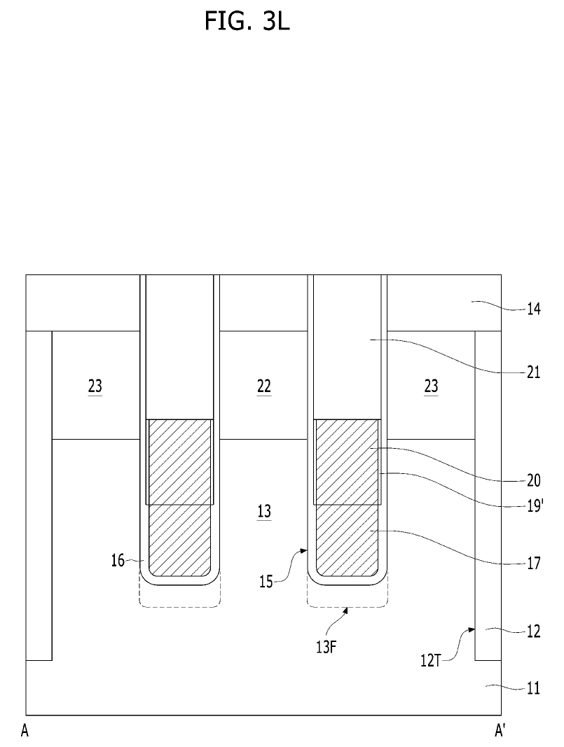

FIGS. 3A to 3L are cross-sectional views illustrating a method for fabricating a semiconductor device in accordance with an embodiment of the present invention. FIGS. 3A to 3L Iillustrate an example of a method for fabricating the semiconductor device shown in FIG. 2A.

Referring to FIG. 3A, an isolation layer 12 may be formed over a substrate 11. An active region 13 may be defined by the isolation layers 12. The isolation layer 12 may be formed by a Shallow Trench Isolation (STI) process. For example, the substrate 11 may be etched to form an isolation trench 12T. The isolation trench 12T may be filled with a dielectric material, and as a result, the isolation layer 12 may be formed. The isolation layer 12 may include, for example, silicon oxide, silicon nitride, or a combination thereof. A Chemical Vapor Deposition (CVD) process or other deposition processes may be used to fill the isolation trench 12T with a dielectric material. A planarization process such as Chemical Mechanical Polishing (CMP) may be used additionally.

Gate trench 15 may be formed in the substrate 11. The gate trench 15 may be formed in a line shape crossing the active region 13 and the isolation layer 12. The gate trench 15 may be formed by using the hard mask layer 14 as an etching mask and performing an etching process onto the substrate 11. The hard mask layer 14 may be formed over the substrate 11 and may have line-shaped openings. The hard mask layer 14 may be formed of a material having an etch selectivity with respect to the substrate 11. The hard mask layer 14 may be a silicon oxide, such as tetra ethyl ortho silicate (TEOS). The gate trench 15 may be formed to be shallower than the isolation trench 12T. The depth of the gate trench 15 may be sufficient to increase the average cross-sectional area of a gate electrode, which will be formed subsequently. Accordingly, the resistance of the gate electrode may be reduced. The bottom edge of the gate trench 15 according to another embodiment of the present invention may have a curvature.

Subsequently, a fin 13F may be formed. In order to form the fin 13F, the isolation layer 12 below the gate trench 15 may be selectively recessed. The structure of the fin 13F may be referred to as the fin 103F illustrated in FIG. 2B.

Referring to FIG. 3B, a gate dielectric layer 16 may be formed on the surface of the gate trench 15 and the hard mask layer 14. Before the gate dielectric layer 16 is formed, etching damage on the surface of the gate trench 15 may be cured. For example, after a sacrificial oxide is formed by a thermal oxidation treatment, the sacrificial oxide may be removed.

The gate dielectric layer 16 may be formed by a thermal oxidation process. The gate dielectric layer 16 may include, for example, silicon oxide. According to another embodiment of the present invention, the gate dielectric layer 16 may be formed by a Chemical Vapor Deposition (CVD) process or an Atomic Layer Deposition (ALD) process. The gate dielectric layer 16 formed by the deposition method may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may be selectively used. The gate dielectric layer 16 may include a stack of silicon oxide and a high-k material, where the high-k material may include a material having a higher areal density of oxygen atom than silicon oxide.

Referring to FIG. 3C, a first gate electrode 17 that fills a portion of the gate trench 15 may be formed over the gate dielectric layer 16. The first gate electrode 17 may include, for example, a metal nitride. For example, the first gate electrode 17 may include titanium nitride (TiN). In particular, according to an embodiment of the present invention, the first gate electrode 17 may include fluorine-free titanium nitride (TiN).

The first gate electrode 17 may be formed by forming a conductive material over the gate dielectric layer 16 and the hard mask layer 14, and then performing a recess process so that the conductive material remains at the bottom portion of the gate trench 15. The recessing process may be performed by a dry etching process, for example, an etch-back process. The etch-back process may be performed using plasma. In particular, according to an embodiment of the present invention, in order to form fluorine-free titanium nitride (TiN), titanium nitride (TiN) may be included using a fluorine-free source gas. Also, cleaning processes using fluorine may be skipped in the cleaning processes that are performed before and after the formation of the first gate electrode 17.

Referring to FIG. 3D, a dipole-inducing source layer 18 may be formed along the profile of the exposed surfaces of the gate dielectric layer 16 and the first gate electrode 17. The dipole-inducing source layer 18 may be formed conformally. The dipole-inducing source layer 18 may be formed by an atomic layer deposition (ALD) process or a chemical vapor deposition (CVD) process. The dipole-inducing source layer 18 may include a dipole-inducing chemical species. For example, the dipole-inducing chemical species may contain lanthanum atoms. The dipole-inducing source layer 18 may include lanthanum oxide (La₂O₃) or a lanthanum oxide monolayer. According to another embodiment of the present invention, the dipole-inducing source layer 18 may include yttrium oxide (Y₂O₃), germanium oxide (GeO₂), ruthenium oxide (Lu₂O₃), or strontium oxide (SrO). The dipole-inducing source layer 18 may be formed to a thickness smaller than that of the gate dielectric layer 16. For example, the thickness of the dipole-inducing source layer 18 may be adjusted to approximately 1/10 of the thickness of the gate dielectric layer 16.

Referring to FIG. 3E, an annealing process ANL may be performed. The annealing process ANL may include rapid thermal annealing (RTA). The dipole-inducing source layer 18 may be exposed to the annealing process ANL. When the annealing process ANL is performed, the dipole-inducing chemical species may be diffused from the dipole-inducing source layer 18. The dipole-inducing chemical species may be diffused into the gate dielectric layer 16 which is in contact with the dipole-inducing source layer 18 to form a reaction product. As a result, a dipole inducing layer 19 may be formed at the interface between the dipole-inducing source layer 18 and the gate dielectric layer 16. The thickness of the dipole inducing layer 19 may be smaller than that of the gate dielectric layer 16. In other words, the dipole inducing layer 19 may have a thickness that is smaller than the thickness of the gate dielectric layer 16 which is substituted with and remaining as the dipole inducing layer 19 by the reaction with the dipole-inducing source layer 18.

For example, when the dipole-inducing chemical species includes lanthanum (La), the dipole-inducing layer 19 may be lanthanum silicate. As described above, the coupling of the dipole-inducing chemical species for formation of dipoles may be referred to as a ‘dipole bond’. In other words, dipole bond may be lanthanum silicate. A reaction product, that is, the dipole inducing layer 19, may not be formed between the surface of the first gate electrode 17 and the dipole-inducing source layer 18 and the first gate electrode 17 and the dipole-inducing source layer 18 may remain as they are.

Referring to FIG. 3F, the dipole-inducing source layer 18 (see FIG. 3E) may be removed. The dipole-inducing source layer 18 (see FIG. 3E) may be removed by a wet etching process. For example, the dipole-inducing source layer 18 (see FIG. 3E) may be removed by a wet etching process using hydrochloric acid (HCL). By applying the wet etching process, it is possible to selectively remove the dipole-inducing source layer 18 (see FIG. 3E) without damaging the gate dielectric layer 16. As described, the dipole-inducing source layer 18 (see FIG. 3E) that is removed after the annealing process ANL (see FIG. 3E) may be referred to as a ‘sacrificial layer including a dipole-inducing chemical species’.

Since the dipole inducing layer 19 is not formed over the first gate electrode 17, the top surface of the first gate electrode 17 may be exposed as the dipole-inducing source layer 18 (see FIG. 3E) is removed.

Referring to FIG. 3G, a second gate electrode layer 20A may be formed over the first gate electrode 17 and the dipole inducing layer 19. The second gate electrode layer 20A may fill the gate trench 15. The second gate electrode layer 20A may include the same metal nitride as the first gate electrode 17. For example, the second gate electrode layer 20A may include titanium nitride (TiN). In particular, according to an embodiment of the present invention, in order to form fluorine-free titanium nitride (TiN), titanium nitride (TiN) may be included using a fluorine-free source gas. Also, cleaning processes using fluorine may be skipped in the cleaning processes that are performed before and after the formation of the second gate electrode layer 20A.

Referring to FIG. 3H, a second gate electrode 20 may be formed. The second gate electrode 20 may be formed by performing a recessing process onto the second gate electrode layer 20A (see FIG. 3G). The top surface of the second gate electrode 20 may be positioned at a lower level than top surface of the active region 13. In this way, as the top surface of the second gate electrode 20 is recessed low, the physical distance between the second gate electrode 20 and the surrounding conductive material (e.g., a contact plug formed through a subsequent process) may be secured sufficiently.

Referring to FIG. 3I, a dipole inducing portion 19’ may be formed. The dipole inducing portion 19’ may contact both sidewalls of the second gate electrode 20. The dipole inducing portion 19’ may be positioned between the second gate electrode 20 and the gate dielectric layer 16. The dipole inducing portion 19’ may include a material having a lower areal density of oxygen atom than the gate dielectric layer 16. Due to such the difference in the areal density of oxygen atom, the dipole inducing portion 19’ and the gate dielectric layer 16 may be able to generate a dipole in a direction to decrease a work function. The dipole may reduce the effective work function value of the second gate electrode 20. For this reason, the dipole inducing portion 19’ may be referred to as a ‘low work function portion’.

In order to form the dipole inducing portion 19’, the exposed portion of the dipole inducing layer 19 (see FIG. 3H) may be selectively removed. For example, the dipole inducing layer 19 (see FIG. 3H) that does not contact the second gate electrode 20 may be removed by a wet etching process. The top surface heights of the dipole inducing portion 19’ and the second gate electrode 20 may be positioned at the same level. The top surface of the dipole inducing portion 19’ may be positioned at a lower level than the top surface of the active region 13.

The dipole inducing portion 19’ may have a form of a spacer that is in contact with the sidewall of the second gate electrode 20. The dipole inducing portion 19’ may not be positioned between the first gate electrode 17 and the second gate electrode 20.

Referring to FIG. 3J, an impurity ion implantation process may be performed targeting the top surface of the dipole inducing portion 19’. The impurity ion implantation process may be performed to remove the unreacted dipole-inducing chemical species that remains in the dipole inducing portion 19’. In other words, the impurity implanted into the dipole inducing portion 19’ by the impurity ion implantation process may form a non-dipole bond that does not affect the dipole characteristics with the unreacted dipole-inducing chemical species remaining in the dipole inducing portion 19’, thereby preventing external diffusion of the unreacted dipole-inducing chemical species. For example, the impurity may include fluorine, but the concept and spirit of the present invention may not be limited thereto. The impurity ion implantation process may be performed by a tilt ion implantation process. According to another embodiment of the present invention, the impurity ions implantation may be performed by a whole surface ion implantation process that is performed onto the top surfaces of the dipole inducing portion 19’ and the second gate electrode 20.

The impurity that is implanted by the impurity ion implantation process may be diffused along the profile of the sidewalls of the dipole inducing portion 19’. The impurity that is implanted by the impurity ion implantation process may be implanted with a dose that is sufficient to remove all the unreacted dipole-inducing chemical species remaining in the dipole inducing portion 19’. For example, when the dipole-inducing chemical species is lanthanum (La) and the impurity is fluorine, the non-dipole bond may be a lanthanum-fluorine (La-F) bond. Since the lanthanum-fluorine bond is very strong and is not broken even by a high-temperature heat treatment, it may be possible to prevent the unreacted lanthanum from being diffused during the subsequent processes or the like. Accordingly, a short between the buried gates and the bit line contacts due to the diffusion of the unreacted dipole-inducing chemical species may be prevented.

According to a comparative example, when the first and second gate electrodes 17 and 20 include impurities for non-dipole bonds, the dipole-inducing chemical species in the dipole-inducing source layer 18 may be diffused to the first and second gate electrodes 17 and 20 during the annealing process for forming the dipole inducing layer 19 shown in FIG. 3E, thus forming unnecessary bonds. As a result, the dipole inducing layer 19 may not be fully formed due to the lack of the dipole-inducing chemical species that may be used to form the dipole bonds between the dipole-inducing source layer 18 and the gate dielectric layer 16.

According to another comparative example, when the impurity ion implantation process is performed without etching the dipole inducing layer 19, the dipole-inducing chemical species of the dipole inducing layer 19 which is positioned at a higher level than the top surface of the second gate electrode 20 (see FIG. 3H) may form unnecessary bonds with the impurity. Since the non-dipole bonds between the dipole-inducing chemical species and the impurity are very strong and it is difficult to remove the non-dipole bonds, there may be residues remaining even after the removal process, and the remaining residues may cause a short between the buried gates and the bit line contacts.

According to another comparative example, when the cleaning process containing impurities is not skipped but performed before and after the formation of the first and second gate electrodes 17 and 20, the impurities remaining on the surface of the gate dielectric layer 16 may form unnecessary bonds on the entire surface of the gate dielectric layer 16 by reacting with the dipole-inducing chemical species that is diffused during the formation of the dipole inducing layer 19 (see FIG. 3H). Since the non-dipole bonds between the dipole-inducing chemical species and the impurities is very strong and it is difficult to remove the non-dipole bonds, there may be residues still remaining even after the removal process, and the remaining residues may cause a short between the buried gates and the bit line contacts.

Therefore, according to an embodiment of the present invention, it is possible to prevent the problems described above by forming the first and second gate electrodes 17 and 20 of a metal nitride containing no impurities, skipping the cleaning processes including impurities that are performed before and after the formation of the first and second gate electrodes 17 and 20, and performing the impurity ion implantation process after forming the dipole inducing portion 19’ whose top surface is positioned at the same level as the top surface of the second gate electrode 20.

Referring to FIG. 3K, a capping layer 21 may be formed over the dipole inducing portion 19’ and the second gate electrode 20. The capping layer 21 may include a dielectric material. The capping layer 21 may include silicon nitride. Subsequently, the capping layer 21 may be planarized to expose the top surface of the hard mask layer 14. During the planarization process of the capping layer 21 or after the planarization process of the capping layer 21, the gate dielectric layer 16 on the top surface of the hard mask layer 14 may be removed. The gate dielectric layer 16 may remain in the gate trench 15.

Referring to FIG. 3L, first and second doped regions 22 and 23 may be formed in the substrate 11. The first and second doped regions 22 and 23 may be formed by an impurity doping process using an implantation process or other doping technology. The first and second doped regions 22 and 23 may be spaced apart from each other by the gate trench 15. In other words, the first and second doped regions 22 and 23 may be positioned in the substrate on both sides of a buried gate structure. The first and second doped regions 22 and 23 may overlap with all or part of the second gate electrode 20 horizontally (in a direction parallel to the surface of the semiconductor substrate). The first gate electrode 17 may not overlap with the first and second doped regions 22 and 23. The first and second doped regions 22 and 23 may be referred to as ‘first and second source/drain regions’.

As the first and second doped regions 22 and 23 are formed, a channel may be defined along the profile of the surface of the gate trench 15.

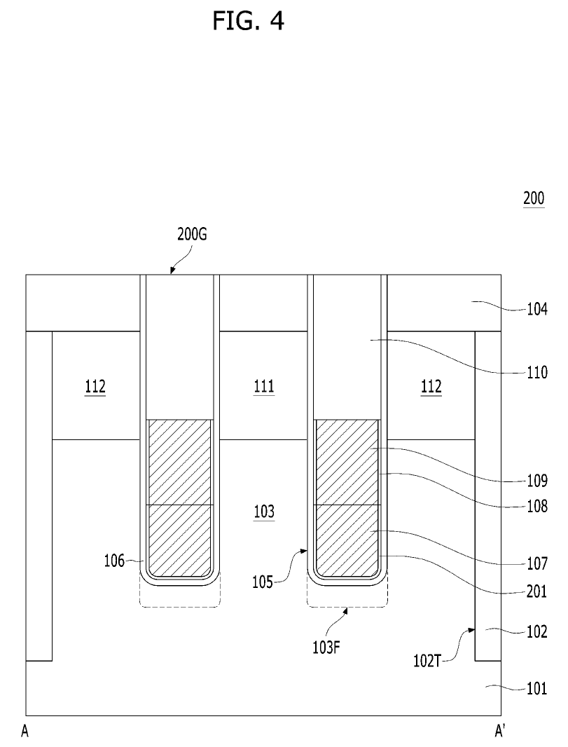

FIG. 4 is a cross-sectional view illustrating a semiconductor device 200 in accordance with another embodiment of the present invention.

Referring to FIG. 4, the semiconductor device 200 may include a substrate 101 and a buried gate structure 200G embedded in the substrate 101. The buried gate structure 200G may include the same structure as that of FIG. 2A, except for a high work function layer 201. The high work function layer 201 may be positioned between the first gate electrode 107 and the gate dielectric layer 106. The high work function layer 201 may have a higher work function than the first and second gate electrodes 107 and 109. The high work function layer 201 may include, for example, a metal nitride or a metal silicon nitride. Herein, the term ‘high work function’ may refer to a work function which is higher than a mid-gap work function of silicon. Also, the term ‘low work function’ may refer to a work function which is lower than the mid-lap work function of silicon. To be specific, the high work function may have a work function which is higher than approximately 4.5 eV, and the low work function may have a work function which is lower than approximately 4.5 eV.

According to an embodiment of the present invention, the resistance Rs may be reduced by increasing the volume of a gate electrode including a metal material.

According to an embodiment of the present invention, it is possible to prevent unnecessary diffusion of unreacted lanthanum (La) through La-F bonds.

According to an embodiment of the present invention, the reliability of a semiconductor device may be secured by preventing a short between a word line and a bit line.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a gate trench in a substrate;
forming a gate dielectric layer over sidewalls and over a bottom surface of the gate trench;
forming a first gate electrode over the gate dielectric layer to gap-fill the bottom surface of the gate trench;
forming a dipole inducing layer including a dipole bond over an exposed surface of the gate dielectric layer;
forming a second gate electrode over the first gate electrode and the dipole inducing layer to gap-fill a portion of the gate trench;
etching the dipole inducing layer to the same level as a top surface of the second gate electrode to form a dipole inducing portion;
performing an impurity ion implantation process for a non-dipole bond onto the dipole inducing portion; and
forming a capping layer to gap-fill a remaining portion of the gate trench over the dipole inducing portion and the second gate electrode.

2. The method of claim 1, wherein the forming of the dipole inducing layer includes:
forming a dipole-inducing source layer including a dipole-inducing chemical species over the first gate electrode and the exposed surface of the gate dielectric layer;
forming a dipole inducing layer including a dipole bond on a sidewall of the gate dielectric layer through an annealing process; and
removing the dipole-inducing source layer.

3. The method of claim 2, wherein the dipole-inducing chemical species includes lanthanum.

4. The method of claim 2, wherein the dipole-inducing source layer includes lanthanum oxide.

5. The method of claim 2, wherein the removing of the dipole-inducing source layer is performed by a wet etching processing using hydrochloric acid (HCL).

6. The method of claim 1, wherein the impurity ion implantation process is performed by a tilt ion implantation process.

7. The method of claim 1, wherein the dipole bond includes lanthanum silicate.

8. The method of claim 1, wherein the non-dipole bond includes a lanthanum-fluorine bond.

9. The method of claim 1, wherein the first and second gate electrodes include impurity-free titanium nitride.

10. The method of claim 1, further comprising:
after the forming of the capping layer,
forming first and second doped regions that are spaced apart from each other by the gate trench by performing an impurity doping process onto the substrate.
